(19) United States
(12) Patent Application Publication
(10) Pub. No.: US 2012/0255919 A1
(43) Pub. Date: Oct. 11, 2012

(54) PANEL TELEVISION MOUNTING ASSEMBLY WITH REVERSIBLE SOUND BAR/SENSOR SHELF

(75) Inventors: Paul R. Jones, San Marcos, CA (US); Anna Martina Marietta, Seatte, WA (US); Jason Charles Woodrow, Seattle, WA (US)

(73) Assignee: WHALEN FURNITURE MANUFACTURING INC., San Diego, CA (US)

(21) Appl. No.: 13/440,636

(22) Filed: Apr. 5, 2012

Related U.S. Application Data
(60) Provisional application No. 61/472,194, filed on Apr. 5, 2011.

(51) Int. Cl. H05K 7/18

(52) U.S. Cl. 211/26

(57) ABSTRACT

A panel television mounting assembly includes a mounting frame, and a reversible shelf for supporting a television accessory either above or below the panel television. The mounting frame includes a back configured and arranged to be secured to a support structure such as a wall or a supporting spine structure on a console, and a front configured and arranged to receive and support a flat panel television. The reversible shelf can be assembled with the mounting frame in a first configuration wherein the shelf is adjacent the top of the mounting frame with for supporting a television accessory above a panel television, or in a second configuration wherein the shelf is adjacent the bottom of the mounting frame for supporting a television accessory below a panel television.

### RELATION TO CO-PENDING APPLICATIONS

This application claims priority to earlier-filed US Provisional Patent Application No. 61/472,194, filed Apr. 5, 2011, the entire contents of which is incorporated herein by reference.

### BACKGROUND AND SUMMARY OF THE INVENTION

The present invention relates to a reversible shelf for a panel television mounting assembly.

The introduction of so-called panel televisions (LCD, plasma, etc.) has created complexity in the task of the purchaser in choosing how to display the panel television, i.e. to support the television on a suitable stand or console, or to mount it from a wall, or to support it above a console. For many years, the market floundered about providing single solution display systems, such as wall mounting brackets, or set top consoles, or support spines to suspend the flat panel above an existing console. However, more recently the present applicant has responded with the creation of a novel console system, known as 3-in-1 display configuration which provides the purchaser with the unique ability to choose the best option that suits the purchaser's needs. This solution is best seen in the Applicant's issued U.S. Pat. No. 8,079,311.

In addition, the introduction of home theater systems and video gaming systems has added even more complexity to the purchaser's task of choosing a functional, yet elegant display configuration. Home theater systems typically include speaker systems which are most desirably mounted adjacent to the flat panel television. Existing display configurations, particularly console systems, provide no options for orienting a center channel speaker or a multi-speaker sound bar relative to the television. Gaming systems, such as Microsoft's® XBOX 360® and the Nintendo® Wii® both include sensor devices which are also most desirably mounted adjacent to the flat panel screen. Likewise, the existing display configurations provide no options for orienting a gaming sensor relative to the television.

Among the objects of the instant invention is the provision of a unique and novel sound bar/sensor shelf which can be supported either above the television or below the television, as well as be adjustable in height in either the upper or lower mounting position.

Another object of the instant invention is the provision of a unique and novel television mounting assembly, including an integrated sound bar/sensor shelf, which is positioned on the mounting frame of the assembly so that the shelf pivots with the mounting frame. In this manner, the shelf rotates along with the television to maintain proper orientation of the sensor or sound bar as located on the shelf relative to the television.

Other objects, features and advantages of the invention shall become apparent as the description thereof proceeds when considered in connection with the accompanying illustrative drawings.

### BRIEF DESCRIPTION OF THE DRAWING FIGURES

In the drawings, which illustrate exemplary modes for carrying out the present invention:

FIG. 1 is a perspective view of a first exemplary embodiment of the television mounting assembly and shelf of the present invention where the shelf is positioned above the television mounting frame;

FIG. 2 is another perspective view thereof where the shelf is reversed and positioned below the television mounting frame;

FIG. 4 is another perspective view thereof;

FIGS. 5A and 5B are perspective views showing assembly of the shelf spine with the mounting frame for supporting the shelf below the mounting frame;

FIGS. 6A and 6B are perspective views showing assembly of the shelf spine with the mounting frame for mounting the shelf above the mounting frame;

FIG. 7 is a rear view of the shelf;

FIG. 8 is a side view of the shelf;

FIGS. 9A and 9B are enlarged cutaway views showing assembly of the shelf with the shelf spine for use above the television;

FIGS. 10A and 10B are enlarged cutaway views showing assembly of the shelf with the shelf spine for use below the television;

FIG. 11 is a perspective view of the left and right panel brackets;

FIG. 12 is a perspective view of the mounting assembly (shelf in upper position) secured to a pivoting mount on the supporting spine of a 3-in-1 console assembly;

FIG. 13 is a perspective view thereof showing the panel brackets mounted to the panel television and the panel brackets being installed on the mounting frame;

FIG. 14 is an enlarged cutaway of the panel bracket being installed onto the mounting frame;

FIG. 15 is a perspective view thereof with the shelf in the upper position above the panel television;

FIG. 16 is a perspective view thereof with the shelf in the lower position below the panel television;

FIG. 17 is a top view of the 3-in-1 console and mounting frame showing rotation of the mounting frame and shelf relative to the console;

FIG. 18 is a perspective view of the mounting assembly (shelf in the upper position) secured to a wall;

FIG. 19 is a perspective view thereof showing the panel brackets mounted to the panel television and the panel brackets being installed on the mounting frame;

FIG. 20 is an enlarged cutaway of the panel bracket being installed onto the mounting frame;

FIG. 21 is a perspective view thereof with the shelf in the upper position above the panel television;

FIG. 22 is a perspective view thereof with the shelf in the lower position below the panel television;

FIG. 23 is a front view of a second exemplary embodiment of the mounting assembly where the shelf is positioned above the television mounting frame;

FIG. 24 is perspective view thereof from the bottom showing assembly of the shelf onto the shelf spine;

FIG. 25 is a an exploded perspective view thereof;

FIG. 26 is another front view thereof where the shelf is positioned below the television mounting frame;

FIG. 27 is a front view of a third exemplary embodiment of the mounting assembly where the shelf is positioned above the television mounting frame;

FIG. 28 is perspective view thereof;

FIG. 29 is another front view thereof where the shelf is positioned below the television mounting frame; and

FIG. 30 is a perspective view from the bottom showing assembly of the shelf onto the shelf spine.

### DETAILED DESCRIPTION OF THE EXEMPLARY EMBODIMENTS

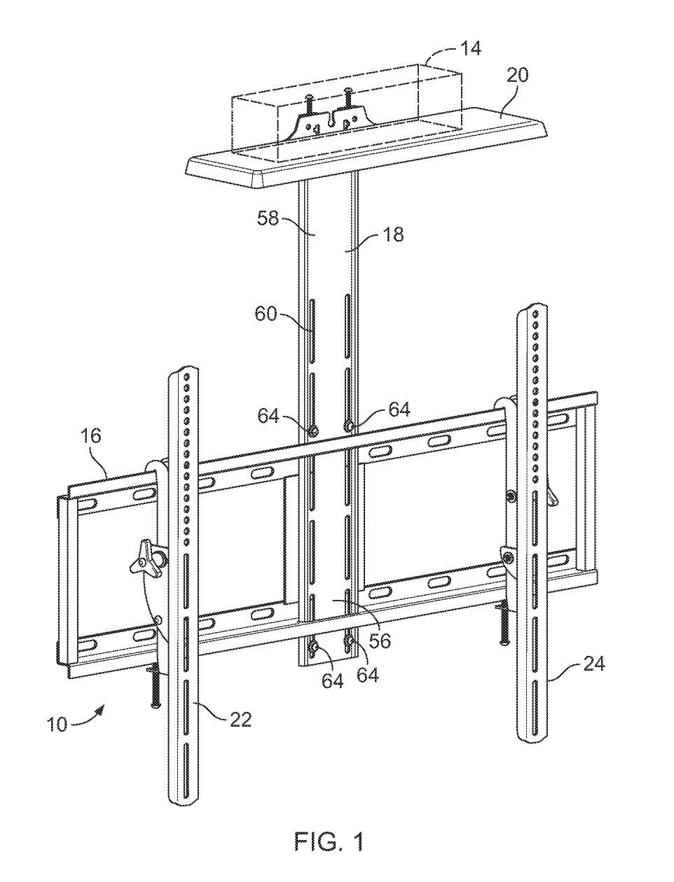

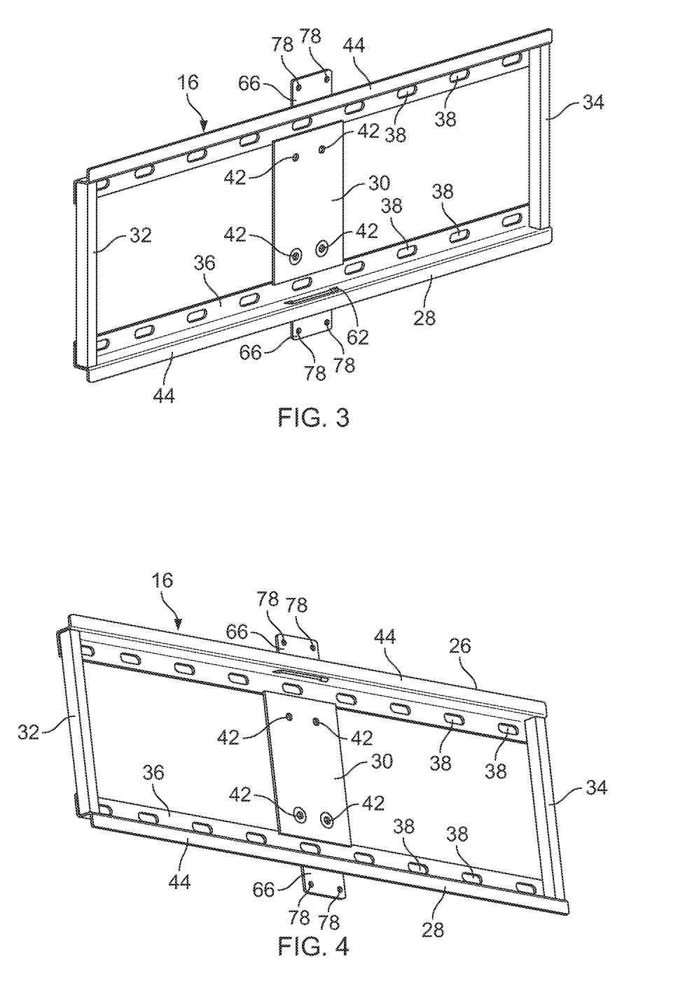

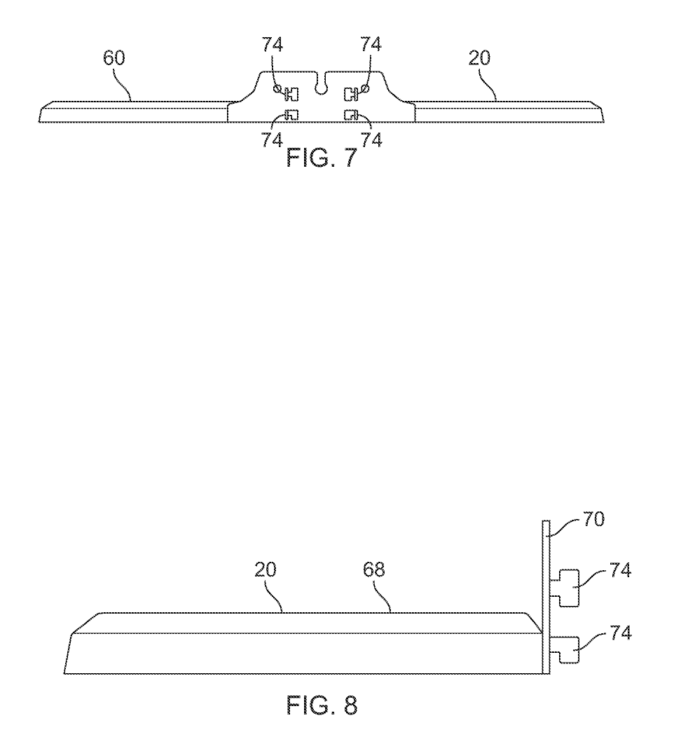

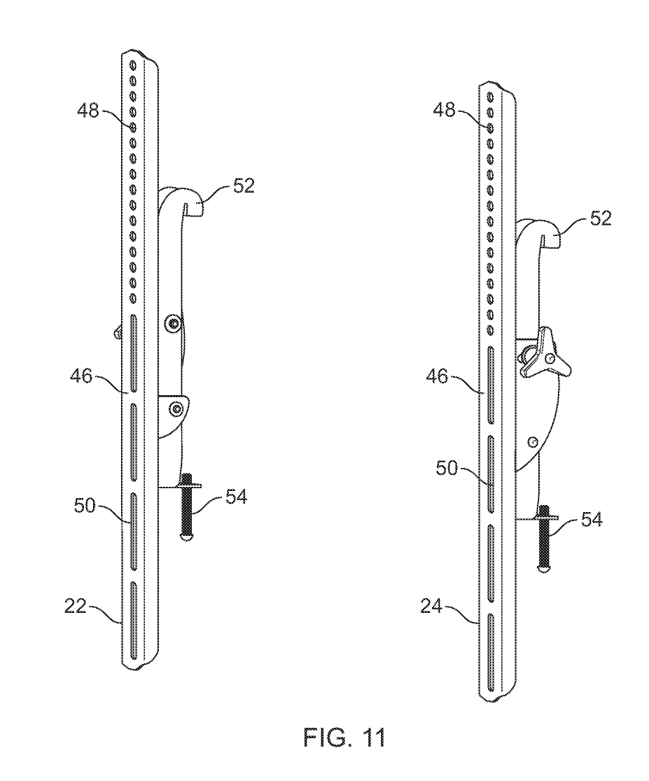

Referring now to the drawings, a first exemplary embodiment of the panel television mounting assembly is illustrated and generally indicated at 10 in FIGS. 1-22. As will be hereinafter described in more detail, an objective of the assembly 10 is to provide a unique and novel shelf which can be reversibly supported either above or below the panel television 12, as well as be adjustable in height in either the upper or lower mounting position. The purpose of the shelf is to orient an accessory 14 relative to the television 12 so that the display is both functional and aesthetically pleasant to the viewer. In the context of the present disclosure, the accessory 14 can include, but should not be limited to, a gaming accessory, such as a gaming sensor which may be preferably oriented above the television 12 (FIG. 1) or a home theater accessory such as a center channel speaker or multi-speaker sound bar which may be preferably oriented below the television 12.

The panel television mounting assembly 10 generally includes a mounting frame 16, a shelf spine 18, a shelf 20 and a pair of panel brackets 22,24.

Referring to FIGS. 1-4, the mounting frame 16 is generally rectangular in shape and includes parallel upper and lower rails 26, 28 connected in the center by a support plate 30 and at the ends by vertical rails 32,34. The back of the mounting frame 16 is configured and arranged to be secured to a support structure, such as a wall or a spine of a console assembly. For wall mounting, the upper and lower rails 26,28 have a rear flange portion 36 with a plurality of slots 38 through which bolts 40 are passed and secured into the wall. For console mounting, the center support plate 30 includes spaced mounting holes 42 for attachment to a spine or other intermediate supporting brackets. The front of the mounting frame 16 is configured and arranged to receive panel brackets 22,24, which in turn support the panel television 12. In this regard, the upper and lower rails 26,28 include a front flange portion 44 which receives the panel brackets 22,24.

Referring briefly to FIGS. 1, 2, 11, 13 and 14, the panel brackets 22,24 include an elongated vertically extending rail portion 46 having a plurality of mounting holes 48 and slots 50 in the front face thereof for securing the bracket 22,24 to the rear surface of the panel television 12. The plurality of mounting holes 48 and slots 50 will accommodate the various standard sizes and spacing of mounting holes in the rear of panel televisions 12. The rear of the panel brackets 22,24 include a pivoting hook 52 and a locking bolt 54 for securing the panel bracket 22,24 to the upper and lower rails 26,28 of the mounting frame 16. The pivoting hook 52 allows for a modest angle of tilt of the panel television 12 when mounted on the mounting frame 16.

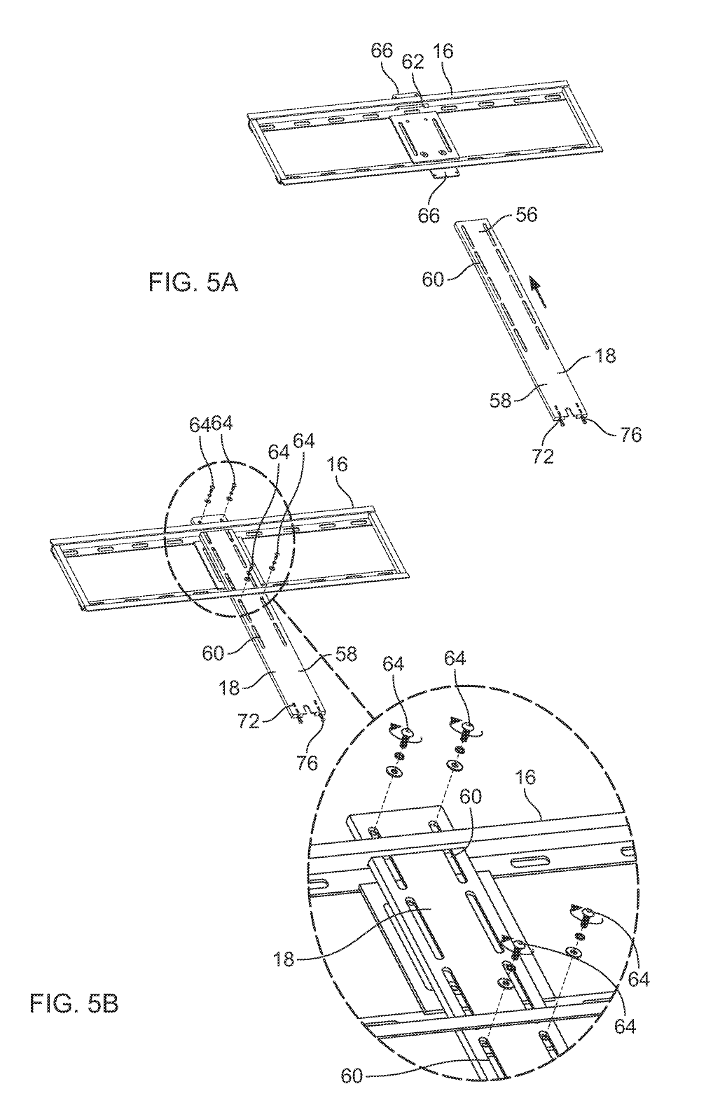

Referring back to FIGS. 1-6, the shelf spine 18 comprises an elongated rectangular panel having a first end 56 and a second end 58 and a plurality of symmetrically opposed mounting slots 60 generally oriented toward the first end 56 thereof. The mounting slots 60 provide for vertical adjustment of the shelf spine 18 relative to the mounting frame 16. The shelf spine 18 can be constructed of any rigid material, such as metal or plastic, which has sufficient strength for supporting the weight of the shelf 20 and any accessory 14 positioned on the shelf 20. The first end 56 of the shelf spine 18 is slidably received into a guide structure formed within the mounting frame 16. More specifically, the guide structure comprises a pair of aligned guide slots 62 formed in the center of the upper and lower rails 26,28 of the mounting frame 16. The shelf spine 18 slides in front of the center plate 30 and is adjustably secured to the mounting frame 16 by fasteners 64 (preferably threaded bolts) which extend through the symmetrical mounting slots 60 and into mating receptacles 64 (preferably mating threaded apertures) in upper and lower opposed anchor plates 66 extending upwardly and downwardly from the upper and lower rails 26,28 (see inset FIG. 5B).

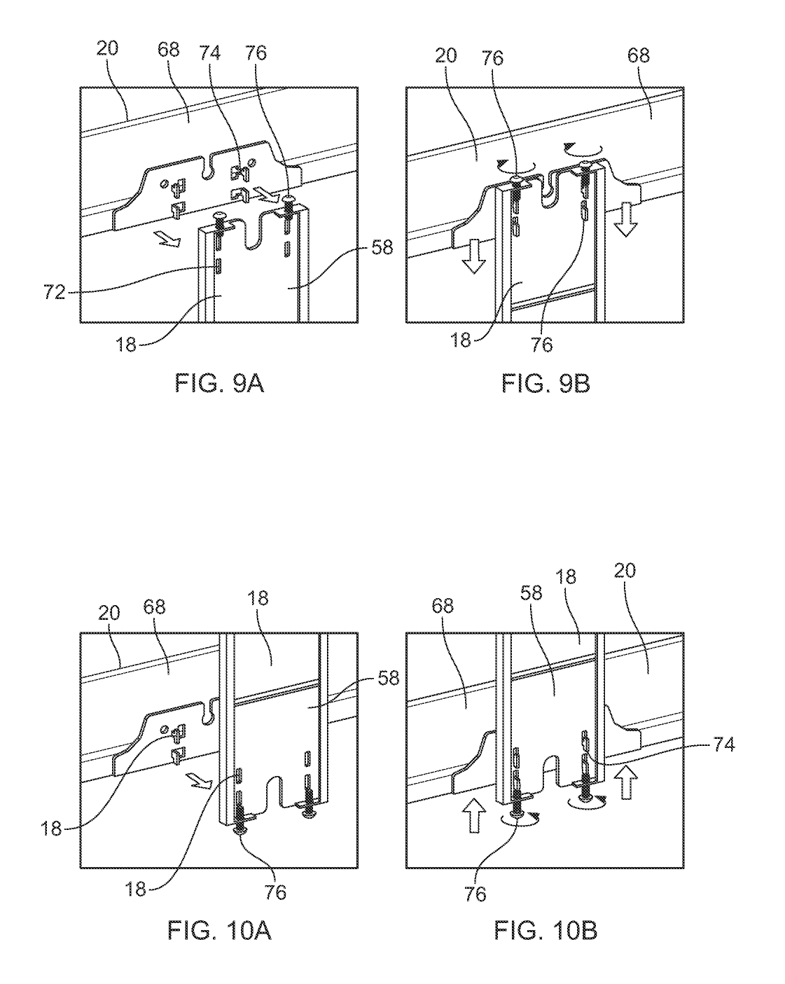

The shelf 20 generally has an upper surface 68 on which the television accessory 12 is positioned and a back edge 70 which is releasably, and reversibly, secured to the second end 58 of the shelf spine 18. The shelf 20 is constructed of metal, but can also be made from any other rigid material, such as plastic, which has sufficient weight for supporting an accessory 14. Turning to FIGS. 7-10, the second end 58 of the shelf spine 18 and the back edge 70 of the shelf 20 include interfitting mating formations to permit the shelf 20 to be reversibly mounted onto the shelf spine 18. More specifically, the second end 58 of the shelf spine 18 is formed with a pair of opposed symmetrical slots 72, while the back edge 70 of the shelf 20 is formed with opposed symmetrical mounting tabs 74 which reversibly interfit with the slots 72 (see FIGS. 9-10). The second end 58 of the shelf spine 18 further includes symmetrical locking bolts 76 for securing the shelf 20 to the shelf spine 18.

In accordance with the teachings herein, the shelf 20 and shelf spine 18 are capable of assembly with the mounting frame 16 in a first configuration where the shelf 20 is adjacent the top of the mounting frame 16 and a second configuration where the shelf 20 is adjacent the bottom of the mounting frame 16.

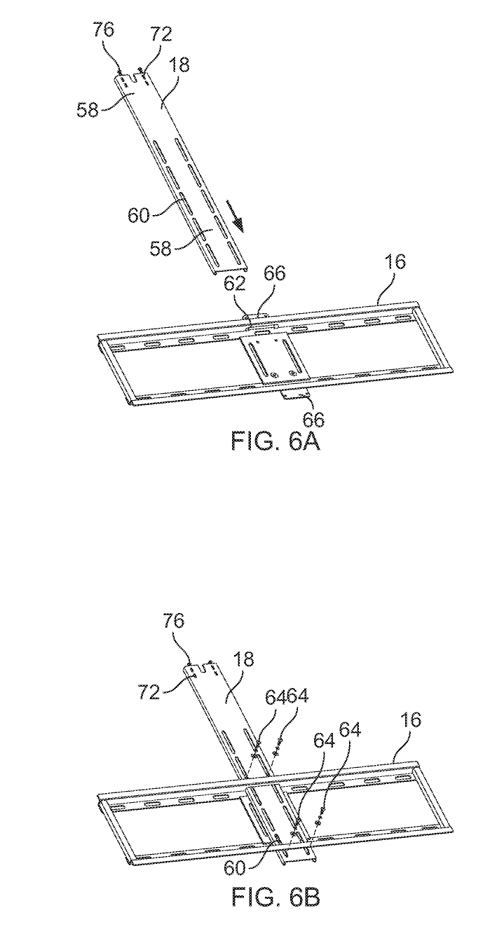

In the first configuration, as best illustrated in FIG. 1, the first end 56 of the shelf spine 18 is slidably received through the aligned guide slots 62 from the top of the mounting frame 16 with the second end 58 of the shelf spine 18 adjacent the top of the mounting frame 16 (see FIGS. 6A and 6B). The shelf spine 18 is adjusted to the desired vertical position relative to the mounting frame 16 and threaded fasteners 64 are passed through the mounting slots 60 and into threaded apertures 78 in the upper and lower anchor plates 66. With the upper surface 68 of the shelf 20 facing upwardly, the shelf mounting tabs 74 are inserted into the mating slots 72 in the second end 58 of the shelf spine 18 and pressed into interfitting engagement (FIG. 9A). The locking bolts 76 are then tightened until the ends hit the shelf tabs 74 (FIG. 9B). The vertical height of the shelf 20 can thereafter be adjusted by loosening the threaded fasteners 64 and sliding the shelf spine 18 relative to the mounting frame 16.

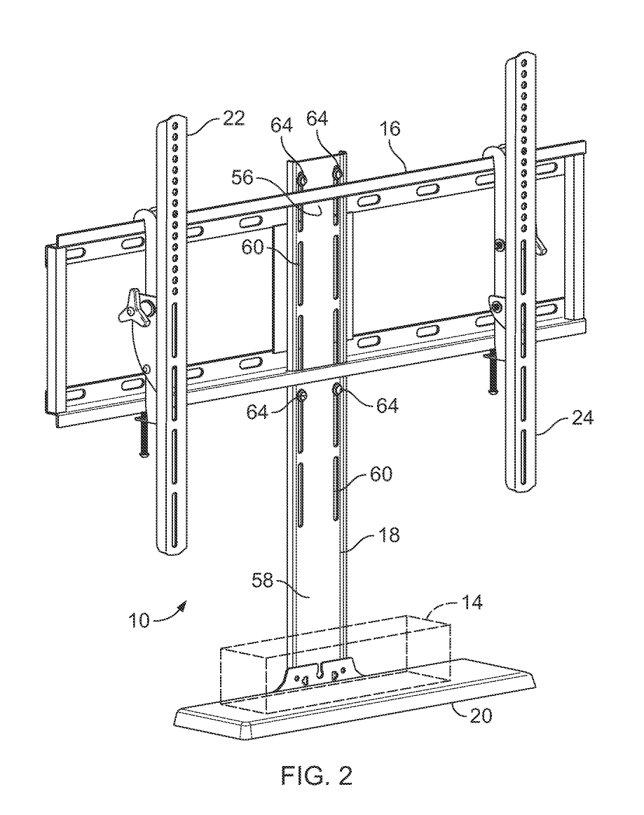

In the second configuration as best illustrated in FIG. 2, the first end 56 of the shelf spine 18 is slidably received through the aligned guide slots 62 from the bottom of the mounting frame 16 with the second end 58 of the shelf spine 18 adjacent the bottom of the mounting frame 16 (see FIGS. 5A and 5B). The shelf spine 18 is adjusted to the desired vertical position relative to the mounting frame 16 and threaded fasteners 64 are passed through the mounting slots 60 and into threaded apertures 78 in the upper and lower anchor plates 66. With the upper surface 68 of the shelf 20 again facing upwardly, the shelf mounting tabs 74 are inserted into the mating slots 72 in the second end 58 of the shelf spine 18 and pressed into interfitting engagement (FIG. 10A). The locking bolts 76 are then tightened until the ends hit the mounting tabs 74 (FIG. 10B).

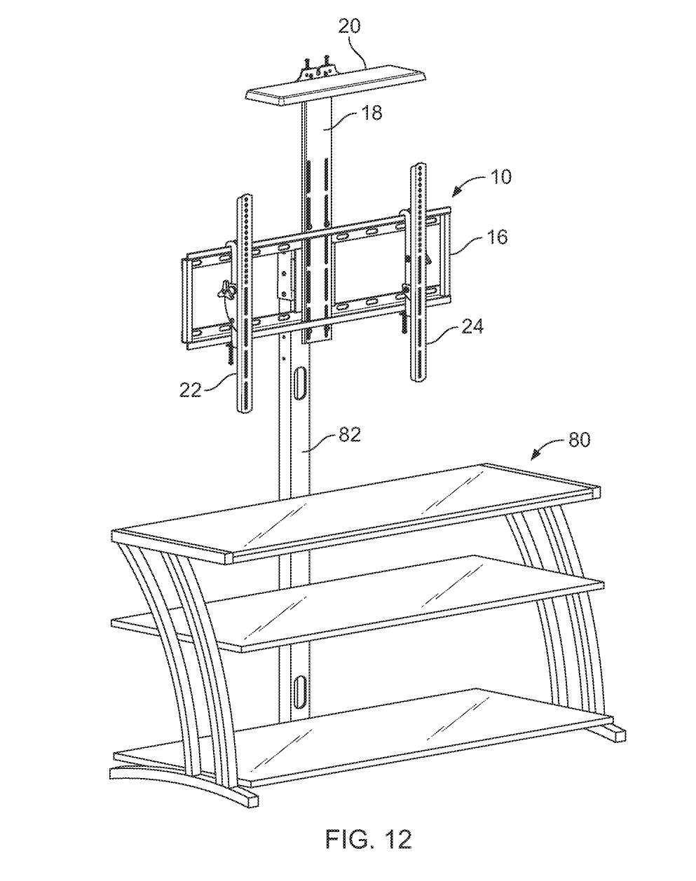

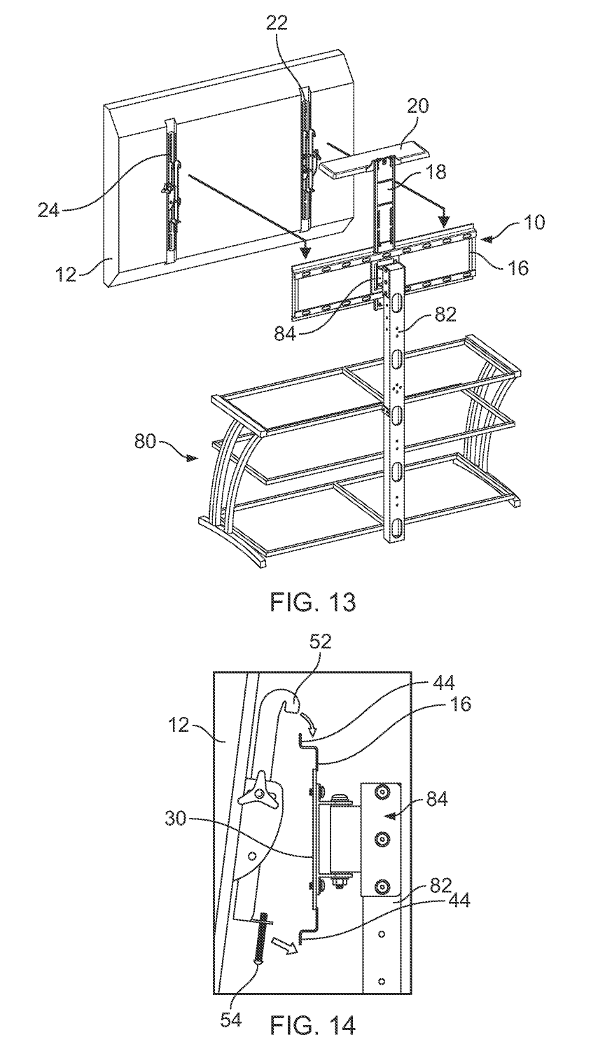

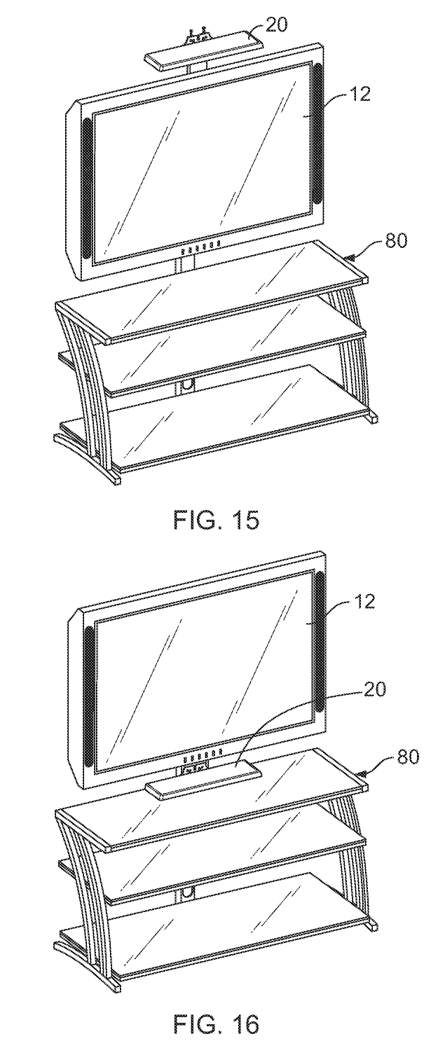

Turning now to FIGS. 12-22, the mounting assembly 10, with its reversible shelf 20, is capable of use in a variety of support and display configurations. In FIGS. 12-17, the mounting assembly 10 is used in conjunction with a 3-in-1 console assembly 80 having a support spine 82 and a pivot bracket 84. The shelf 20 is assembled in the first or upper configuration. The back of the center support plate 30 of the mounting frame 16 is secured to a front portion of the pivot bracket 84 and the back of the pivot bracket 84 is secured to the upper end of the long support spine 82. The lower end of the long spine 82 is in turn secured to the back of the console 80 whereby the mounting assembly 10 is suspended over the upper shelf of the console 80. In FIGS. 13-14, the panel brackets 22,24 are mounted to the panel television 12, the hooks 52 are set over the front flange 44 of the mounting frame 16 and the panel television 12 lowered into engagement. Thereafter, the locking bolts 54 are tightened to lock the television 12 onto the mounting frame 16. The fully assembled configuration with the television mounted is illustrated in FIG. 15. A fully assembled configuration with the shelf 20 in the second or lower configuration and the television 12 mounted is illustrated in FIG. 16.

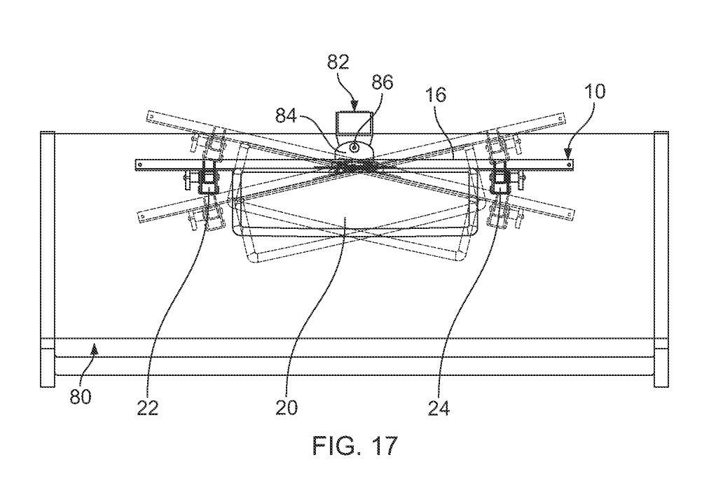

An important functional feature of the mounting assembly is illustrated in FIG. 17 where it can be seen that the mounting frame 16 and the shelf 20 rotate together about the pivot axis 86 of the pivot bracket 84 (See broken lines in FIG. 17). In the context using of the shelf 20 to support a television accessory 14, it is important to the viewer that the accessory 14 pivot in conjunction with the television 12. In the prior art, where the accessory 14 was simply positioned on the upper shelf of the console 80, and the television 12 was rotated for better viewing, the accessory 14 remained facing forward (disoriented from the viewer). In the case of a speaker, the viewer may not get the full sound effect. In the case of a gaming sensor, the gamer would have to adjust the position of the gaming sensor separately from the television. The present configuration, where the shelf 20 is secured to the mounting frame 16 rather than the console 80 or spine 82, allows the shelf 20 to automatically pivot along with the television 12 and keeps the accessory 14 properly oriented with respect to the television at all times.

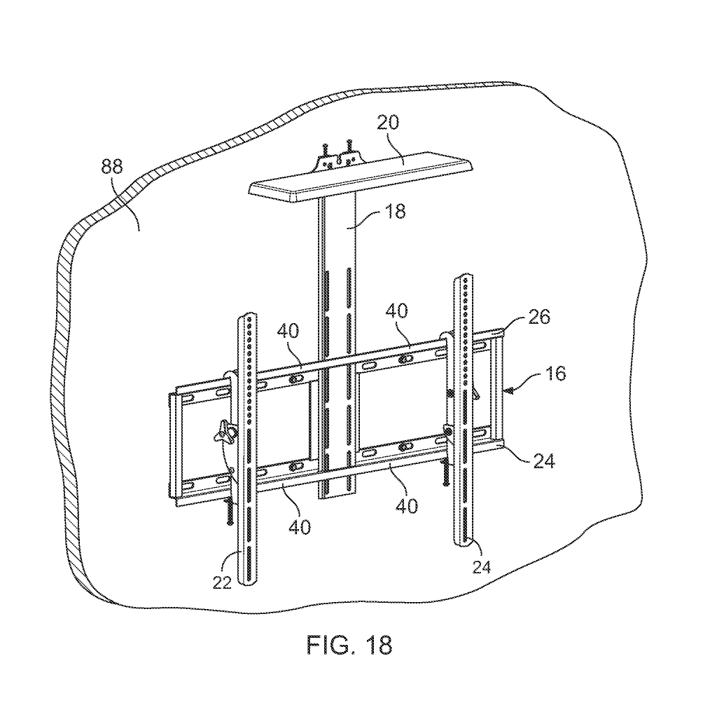

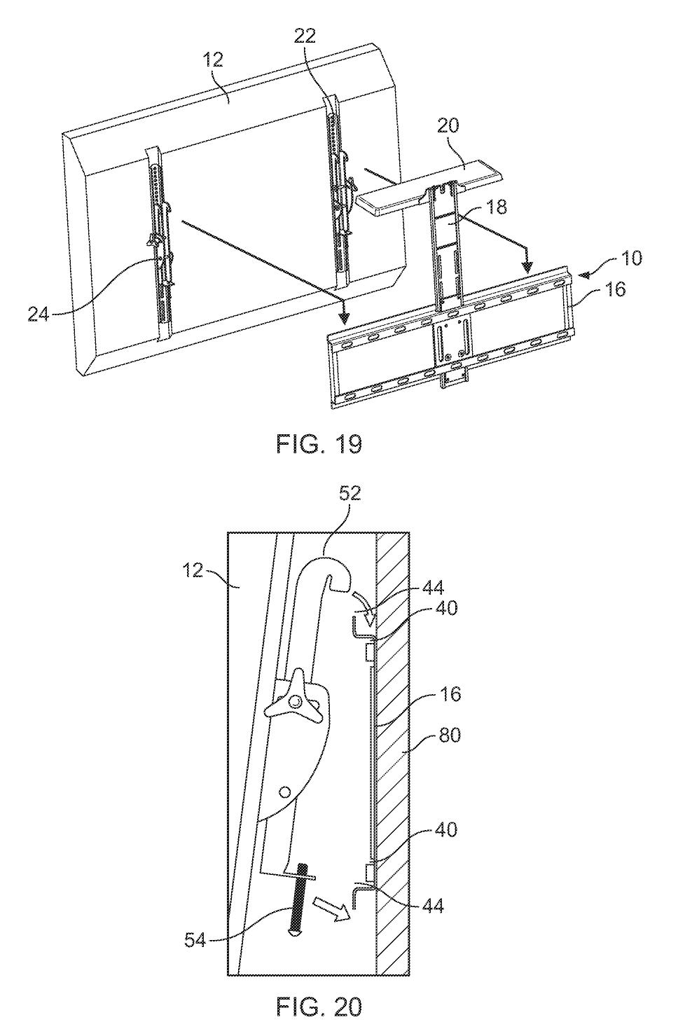

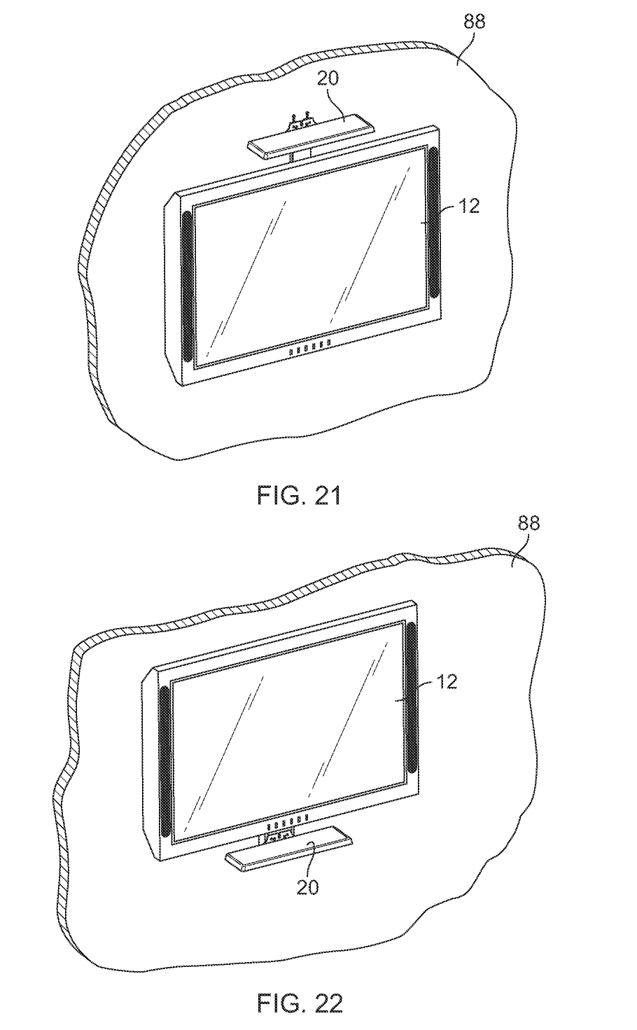

In FIGS. 18-22, the mounting assembly 10 is directly mounted to a wall 88 with wall bolts 40 passed through the upper and lower rails 26,28 of the mounting frame 16 into the wall 88. The shelf 20 is assembled in the first or upper configuration. In FIGS. 19-20, the panel brackets 22,24 are mounted to the panel television 12, the hooks 52 are set over the front flange 44 of the mounting frame 16 and the television 12 lowered into engagement. Thereafter, the locking bolts 54 are tightened to lock the television 12 onto the mounting frame 16. The fully assembled configuration with the television 12 mounted is illustrated in FIG. 21. A fully assembled configuration with the shelf 20 in the second or lower configuration and the television 12 mounted is illustrated in FIG. 22.

The mounting assembly 10 can also be utilized in another configuration where the television 12 is supported on the upper shelf of a conventional console assembly 80 such as shown in FIG. 16 (no support spine) and the mounting assembly 10 is used to support an accessory above the television. The television 12 would utilize its existing stand (not shown) to support it on the console 80, and the mounting assembly 10 would be installed onto the back of the television. The shelf spine 18 and shelf 20 would be assembled with the mounting frame 16 in the first configuration (above the mounting frame 16). Panel brackets 22,24 would be installed on the back of the television and the mounting frame 16 (with the shelf 20) assembled with the panel brackets to support the shelf above the television.

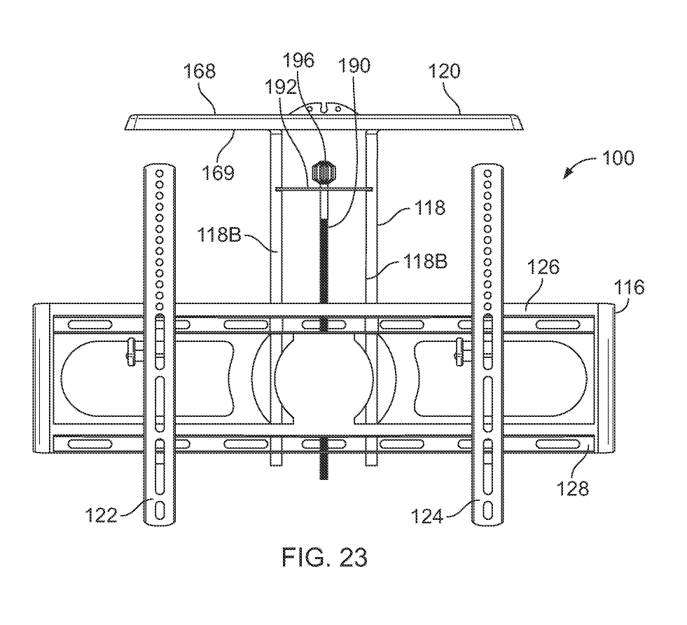

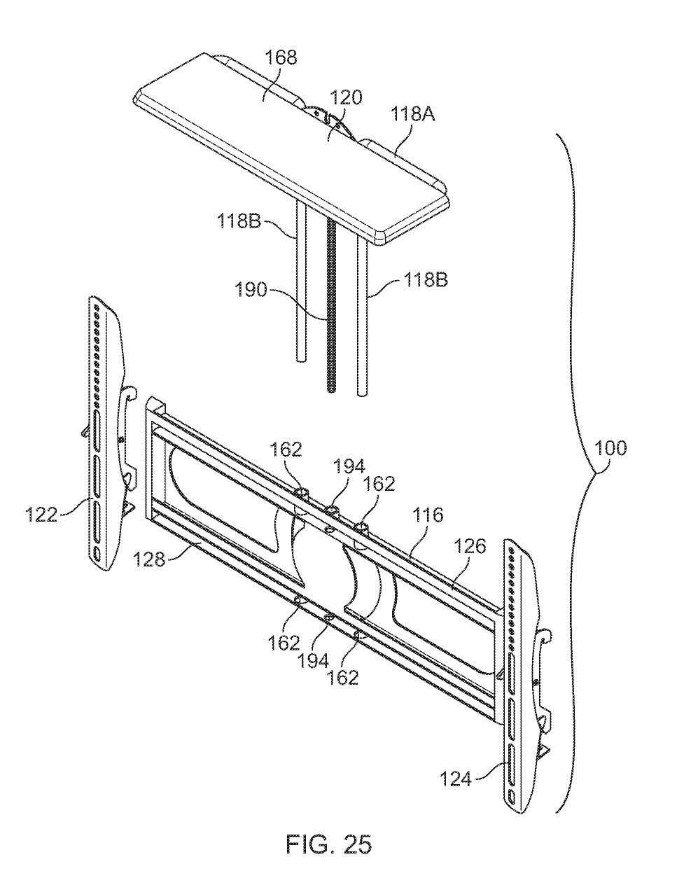

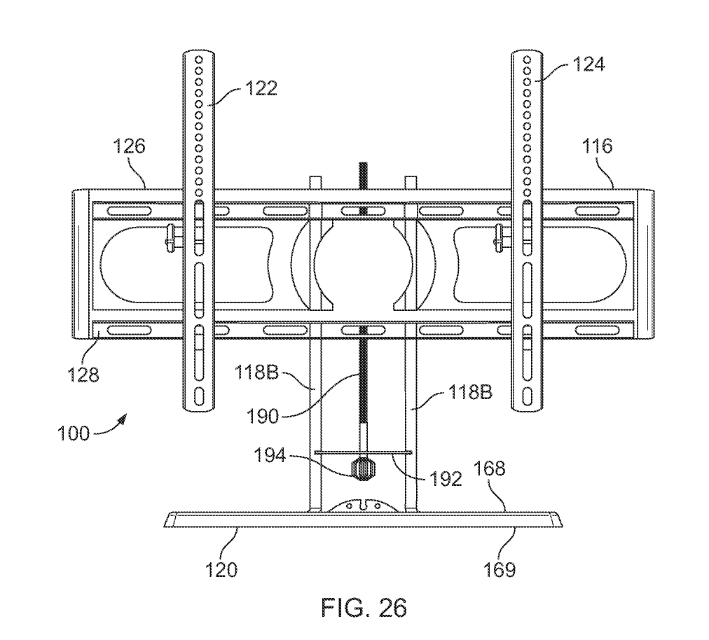

A second exemplary embodiment of the panel television mounting assembly is generally indicated at 100 in FIGS. 23-26. The mounting assembly 100 comprises the same basic components as the first embodiment, namely a mounting frame 116, a shelf spine 118, a reversible shelf 120 and a pair of panel brackets 122,124. Functionality and use of the reversible shelf spine 118 and shelf 120 remain relatively the same. However, the specific implementation of the shelf spine 118, shelf 120, guide structure, adjustment mechanism and locking mechanism is different.

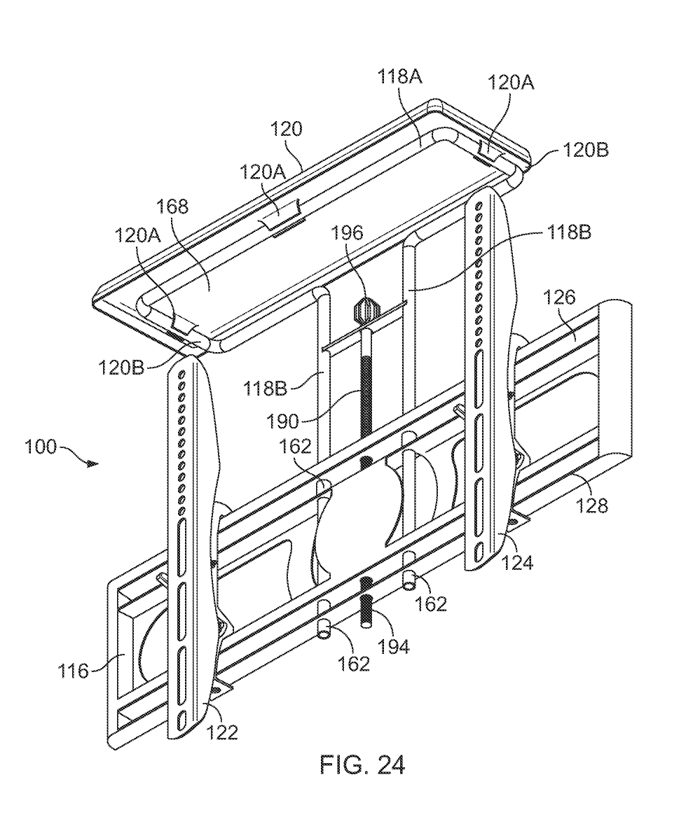

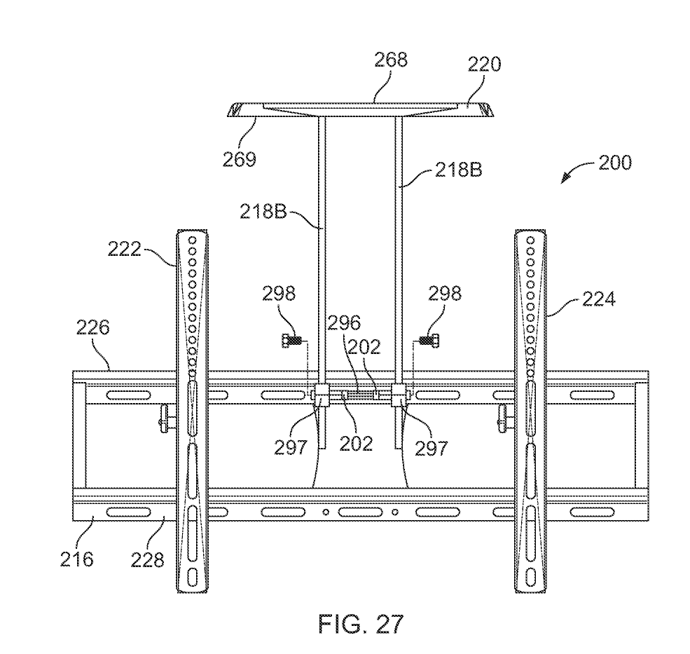

In this regard, the shelf 120 comprises a single molded plastic part having an upper surface 168 and a lower surface 169. The shelf 20 can also be made from any other rigid material, such as stamped metal, which has sufficient weight for supporting an accessory 14. The shelf spine 118 comprises a tubular metal frame having a rectangular base portion 118A and two elongated support rods 118B extending from the base portion 118A. The bottom surface 169 of the shelf 120 is snap received onto the base portion 118A of the shelf spine 118 by means of plastic tabs 120A molded into the lower surface 169 of the shelf 120 (see FIG. 24). The sides of the base portion 118A extend through notches 120B in the rear edge of the shelf 120 then bend inwardly and finally turn downwardly to form the two support rods 118B. Assembly with the mounting frame 116 is accomplished by passing the support rods 118B downwardly (FIGS. 23-26) or upwardly (FIG. 27) through aligned pairs of spaced guide holes 162 in the upper and lower rails 126, 128 of the mounting frame 116. The support rods 118B are able to freely slide upwardly and downwardly through the guide holes 162 to provide vertical positioning of the shelf 120 relative to the mounting frame 116. The shelf 120 is adjusted and locked in position relative to the mounting frame 116 by a threaded rod 190 which passes through a cross bar 192 extending between the guide rods 118B and into a threaded aperture 194 in either the upper rail 126 or the lower rail 128, or both, depending on configuration. The upper end of the threaded rod 190 includes a knob 196 to facilitate rotation thereof. Rotation of the rod 190 causes a corresponding upward or downward movement of the shelf 120.

In the upper configuration (FIGS. 23-26), the shelf 120 is raised or lowered relative to the frame 116 such that the shelf 120 sits just above the edge of the television. In the lower configuration (FIG. 27), the shelf spine 118 is reversed and the shelf 120 snapped on in a reverse orientation so that the upper surface 168 faces upwardly. The rectangular base portion 118A sits beneath the shelf 120 and the support rods 118B extend upwardly from the shelf 120 toward the lower rail 128 of the mounting frame 116. As briefly described above, the lower rail 128 has a matching set of aligned guide holes 162 and a threaded aperture 194 for receiving the threaded rod 190. The shelf assembly 120 is then adjusted so that the shelf 120 sits just below the lower edge of the television.

Turning to FIGS. 27-30, a third exemplary embodiment is generally indicated at 200. The third embodiment 200 includes the same shelf 220 and shelf support 218 as the second embodiment however, the guide structure and locking structure now comprise a U-shaped guide bracket 296 with spaced parallel guide tubes 297 and set screws 298.

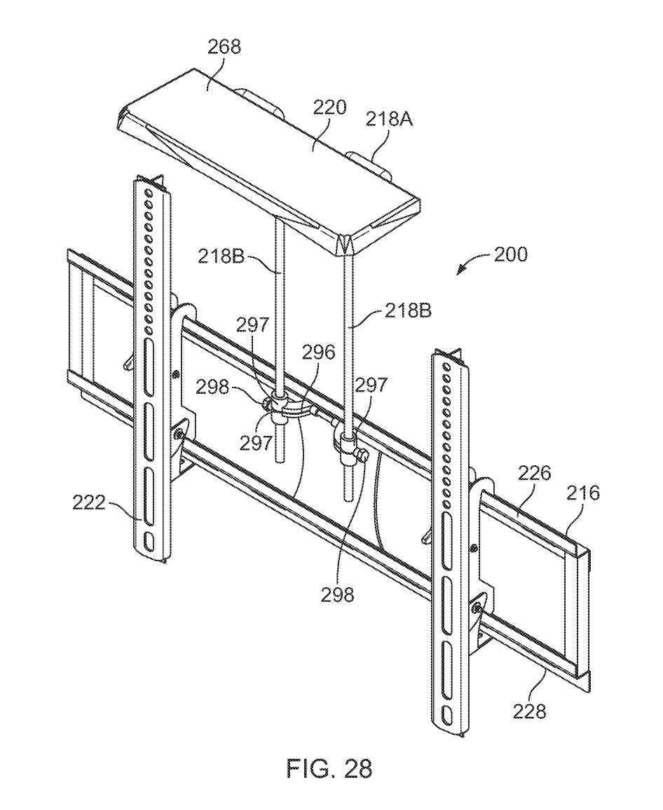

In a first configuration, as shown in FIGS. 27 and 28, the guide bracket 296 is secured to the upper rail 226 of the mounting frame 216 with bolts 202 that extend through the guide bracket 296 and into the upper rail 226. The shelf 220 is snapped onto the base portion 218A of the shelf spine 218 so that the guide rods 218B extend downwardly from the bottom surface 269. The guide rods 218B are slidably received through the guide tubes 297 in the guide bracket 296, adjusted to the desired height, and then locked in position by tightening the set screws 298 received in the side surfaces of the guide tubes 297.

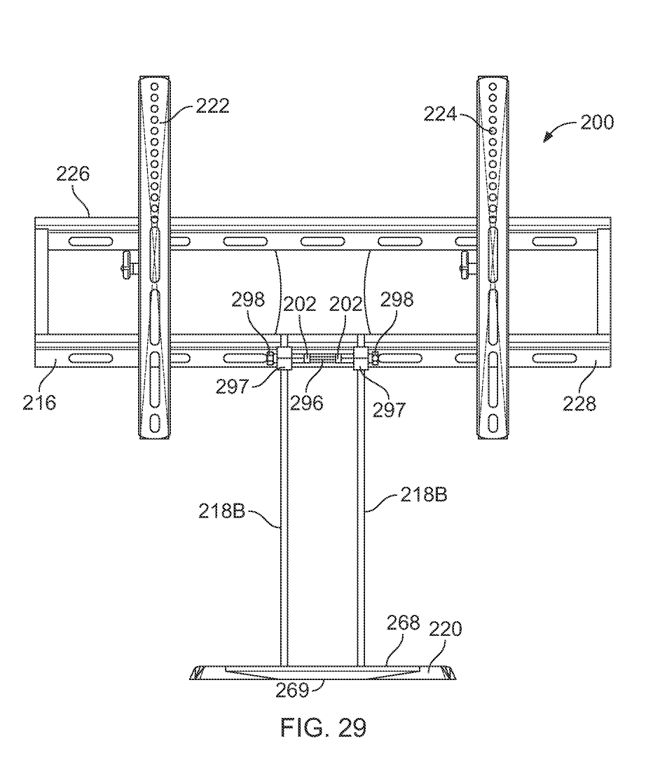

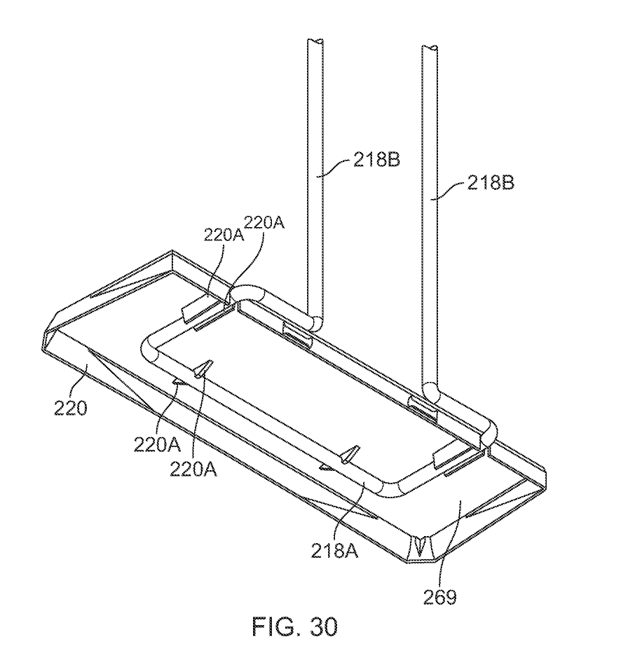

Turning to FIG. 29, the shelf spine 218 is reversed and the shelf 220 snapped on in a reverse orientation (FIG. 30) so that the upper surface 268 still faces upwardly. The rectangular base portion 218A sits beneath the shelf 220 and the guide rods 218B extend upwardly from the shelf 220 toward the lower rail. The guide bracket 296 is secured to the lower rail 228 of the mounting frame 216 with bolts 202 that extend through the guide bracket 216 and into the lower rail 228. The guide rods 218B are received through the guide tubes 297, adjusted to the desired height and locked in place by tightening the set screws 298.

While there is shown and described herein certain specific structure embodying the invention, it will be manifest to those skilled in the art that various modifications and rearrangements of the parts may be made without departing from the spirit and scope of the underlying inventive concept and that the same is not limited to the particular forms herein shown and described except insofar as indicated by the scope of the appended claims.

What is claimed is:

1. A panel television mounting assembly comprising:
a mounting frame having a back configured and arranged to be secured to a support structure, and a front configured and arranged to receive and support a flat panel television,
said mounting frame having a top and a bottom;
a shelf spine having a first end and a second end;
a shelf having an upper surface,
said shelf being releasably securable to said second end of said shelf spine,
said shelf spine being capable of assembly with said mounting frame in a first configuration wherein said second end of said shelf spine and said shelf are adjacent said top of said mounting frame with said upper surface of said shelf facing upwardly for supporting a television accessory above a panel television received on said mounting frame,
said shelf spine being capable of assembly with said mounting frame in a second configuration wherein said second end of said shelf spine and said shelf are adjacent said bottom of said mounting frame with said upper surface of said shelf facing upwardly for supporting a television accessory below a panel television received on said mounting frame.

2. The panel television mounting assembly of claim 1 wherein said shelf spine is releasably securable in a plurality of positions relative to said mounting frame when assembled in said first configuration, and further wherein said shelf spine is releasably securable in a plurality of positions relative to said mounting frame when assembled in said second configuration.

3. The panel television mounting assembly of claim 1 further comprising left and right panel brackets each having a front configured and arranged to mate with the back of a panel television, and a rear configured and arranged to mate with the front of said mounting frame.

4. The panel television mounting assembly of claim 2 further comprising left and right panel brackets each having a front configured and arranged to mate with the back of a panel television, and a rear configured and arranged to mate with the front of said mounting frame.

5. A panel television mounting assembly comprising:
a mounting frame having a back configured and arranged to be secured to a support structure, and a front configured and arranged to receive and support a flat panel television,
said mounting frame having a top and a bottom;
a guide structure extending between said top and said bottom of said mounting frame;
a shelf spine having a first end slidably receivable in said guide structure and further having a second end;
a shelf having an upper surface,
said shelf being releasably securable to said second end of said shelf spine,
said shelf spine being capable of assembly with said guide structure in a first configuration wherein said second end of said shelf spine and said shelf are adjacent said top of said mounting frame with said upper surface of said shelf facing upwardly for supporting a television accessory above a panel television received on said mounting frame,
said shelf spine being releasably securable in a plurality of positions relative to said mounting frame when assembled in said first configuration,
said shelf spine being capable of assembly with said guide structure in a second configuration wherein said second end of said shelf spine and said shelf are adjacent said bottom of said mounting frame with said upper surface of said shelf facing upwardly for supporting a television accessory below a panel television received on said mounting frame,
said shelf spine being releasably securable in a plurality of positions relative to said mounting frame when assembled in said second configuration.

6. The panel television mounting assembly of claim 5 wherein said shelf spine comprises an elongated panel and said guide structure comprises aligned guide slots in said top and said bottom of said mounting frame.

7. The panel television mounting assembly of claim 6 wherein said shelf spine includes a plurality of elongated slots, said shelf spine being releasably and adjustably secured to said mounting frame by fasteners extending through said slots and into mating receptacles in said mounting frame.

8. The panel television mounting assembly of claim 5 wherein said shelf spine comprises spaced guide rods.

9. The panel television mounting assembly of claim 8 wherein said guide structure comprises aligned pairs of guide apertures in said top and said bottom of said mounting frame.

10. The panel television mounting assembly of claim 9 wherein said mounting assembly further comprises a threaded adjustment rod passing through a cross bar extending between said guide rods and into a threaded aperture in said mounting frame.

11. The panel television mounting assembly of claim 8 wherein said guide structure comprises a guide bracket including spaced guide tubes, said guide tubes including set screws for adjustably locking said guide rods.

12. The panel television mounting assembly of claim 5 further comprising left and right panel brackets each having a front configured and arranged to mate with the back of a panel television, and a rear configured and arranged to mate with the front of said mounting frame.

13. The panel television mounting assembly of claim 7 further comprising left and right panel brackets each having a front configured and arranged to mate with the back of a panel television, and a rear configured and arranged to mate with the front of said mounting frame.

14. The panel television mounting assembly of claim 8 further comprising left and right panel brackets each having a front configured and arranged to mate with the back of a panel television, and a rear configured and arranged to mate with the front of said mounting frame.

15. The panel television mounting assembly of claim 9 further comprising left and right panel brackets each having a front configured and arranged to mate with the back of a panel television, and a rear configured and arranged to mate with the front of said mounting frame.

16. The panel television mounting assembly of claim 11 further comprising left and right panel brackets each having a front configured and arranged to mate with the back of a panel television, and a rear configured and arranged to mate with the front of said mounting frame.

17. The flat panel television mounting assembly of claim 5 wherein said support structure comprises a pivot bracket.

18. The flat panel television mounting assembly of claim 17 wherein said support structure further comprises a support spine, said pivot bracket having a back secured to said support spine and a front secured to a back of said mounting frame.

19. The flat panel television mounting assembly of claim 18 further comprising a console, said spine having a lower end secured to said console wherein said mounting frame is supported above said console.
